(19) United States
(12) Patent Application Publication
(10) Pub. No.: US 2024/0243006 A1
(43) Pub. Date: Jul. 18, 2024

(54) SYSTEMS AND METHODS FOR BONDING SEMICONDUCTOR DEVICES

(71) Applicant: Tokyo Electron Limited, Tokyo (JP)

(72) Inventors: Scott Lefevre, Albany, NY (US); Arkalgud Sitaram, Albany, NY (US); Kevin Ryan, Albany, NY (US); Ilseok Son, Albany, NY (US); Panupong Jaipan, Albany, NY (US)

(21) Appl. No.: 18/388,564

(22) Filed: Nov. 10, 2023

Related U.S. Application Data
(60) Provisional application No. 63/439,517, filed on Jan. 17, 2023.

(51) Int. Cl. H01L 21/762; H01L 21/321

(52) U.S. Cl. CPC H01L 21/76251; H01L 21/3212; H01L 21/76243

(57) ABSTRACT

In some implementations, a method may include providing a silicon on insulator (SOI) substrate having a first semiconductor layer, a buried oxide layer over the first semiconductor region, and a second semiconductor region over the buried oxide, the second semiconductor region having a plurality of recesses exposing the underlying buried oxide, each recess having a shape and size configured to accommodate a die. In addition, the device may include bonding a plurality of semiconductor dies to the buried oxide through the plurality of recesses.

### CROSS REFERENCE TO RELATED PATENTS AND APPLICATIONS

The present application claims the benefit of U.S. Provisional Application No. 63/439,517 filed on Jan. 17, 2023, which is incorporated herein by reference in its entirety.

### TECHNICAL FIELD

This disclosure relates to semiconductor devices and methods of bonding a plural number of semiconductor dies to substrates.

### BACKGROUND

The semiconductor industry has experienced rapid growth due to continuous improvements in the minimum feature size, which allows more components to be integrated into a given area. As the demand for miniaturization, higher speed, and greater bandwidth, as well as lower power consumption and latency has grown recently, there has grown a need for smaller and more creative packaging techniques of semiconductor dies.

Direct bonding and hybrid bonding have gained interest to form so called 3D circuits. In direct bonding a die or wafer is provided with a bonding layer, typically a dielectric that has been treated to make the surface more bondable with other dielectric or semiconductor surfaces. The die or wafer is brought together with a similarly treated die or wafer to form a bonded pair. While wafer to wafer bonding allows for batch processing, yield issues tend to compound, which is known to decrease usable bonded pairs of dies. In other words, when two dies are bonded, both individual dies must be fully functional for the pair to be fully functional. However, non-performing dies may be randomly distributed across a wafer, which increases the possibility of bonded pairs having one die that is within a specification bonded to another that is not within a required specification (i.e. nonfunctional). One way to address this issue is to test the wafer to determine which dies are so-called known good dies and then reconstitute these dies into a new wafer or panel to reduce or even eliminate the compounded yield issue.

FIG. 1 shows a conventional process of bonding dies to a wafer or other substrate such as silicon. The dies are prepared and bonded to the substrate according to well-known and established techniques. The dies may be placed face down so that the faces of the dies are aligned in the same plane. However, the dies will often have different thicknesses. Thus, a planarizing dielectric is formed over and around the dies. The planarizing die must be sufficiently thick to fill in the area between adjacent dies. This requires a long process of formation and leads to thick regions of the planarizing layer to be formed over the dies. The regions of material over the die may be so thick that a conventional chemical mechanical process may not be practical or effective to remove the material. In this case, those portions of the planarizing dielectric must be trimmed using a laser ablation process. However, issues can arise with this process. For example, aligning the laser ablation tool with the stage, and in turn the substrate and target regions for trimming, can be challenging. This misalignment can lead to misalignment of the laser to the target region of up to several microns. Moreover, there is non-uniformity in the thickness of the dielectric, roughness, and surface undulation across the surface, which makes laser trimming difficult. The ablation process can generate undesirable debris that can be 1-2 um thick, which may require additional wet etching to remove. Such wet etching can further roughen the surface. Finally, since Si is transparent to the light coming from the laser, a 2 um thickness of dielectric is required over the die to ensure the laser does not damage it. As such, it would be desirable to reduce the surface variation in the planarizing layer so that laser ablation would no longer be necessary.

### SUMMARY

At least one aspect of the present disclosure is directed to a method for manufacturing semiconductor packages.

In one general aspect, a method may include providing a silicon on insulator (SOI) substrate having a first semiconductor region, a buried oxide layer over the first semiconductor region, and a second semiconductor region over the buried oxide, the second semiconductor region having a plurality of recesses exposing the underlying buried oxide, each recess having a shape and size configured to accommodate a die. The method may also include bonding a plurality of semiconductor dies to the buried oxide through the plurality of recesses. Other embodiments of this aspect include corresponding computer systems, apparatus, and computer programs recorded on one or more computer storage devices, each configured to perform the actions of the methods.

Implementations may include one or more of the following features. A method may include forming a planarizing layer over the second semiconductor region and the semiconductor dies. The method may include performing a chemical mechanical polish (CMP) process to the planarizing layer to reduce surface variation of the planarizing layer. The method may include bonding a handle wafer to the planarizing layer after the CMP process. The method may include separating the first semiconductor region from the buried oxide layer after bonding the handle wafer to the planarizing layer. The method may also include a step in which, after separating the first semiconductor region from the buried oxide layer, removing the buried oxide layer to expose the dies and the second semiconductor region. The dies may have a hybrid bonding surface such that exposing the dies exposes hybrid bonding surfaces of the dies. The method may include performing a hybrid bonding process to physically bond and electrically connect the dies to one or more functional substrates. Implementations of the described techniques may include hardware, a method or process, or a computer tangible medium.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a method according to a conventional process.

FIG. 2 illustrates a method according to some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

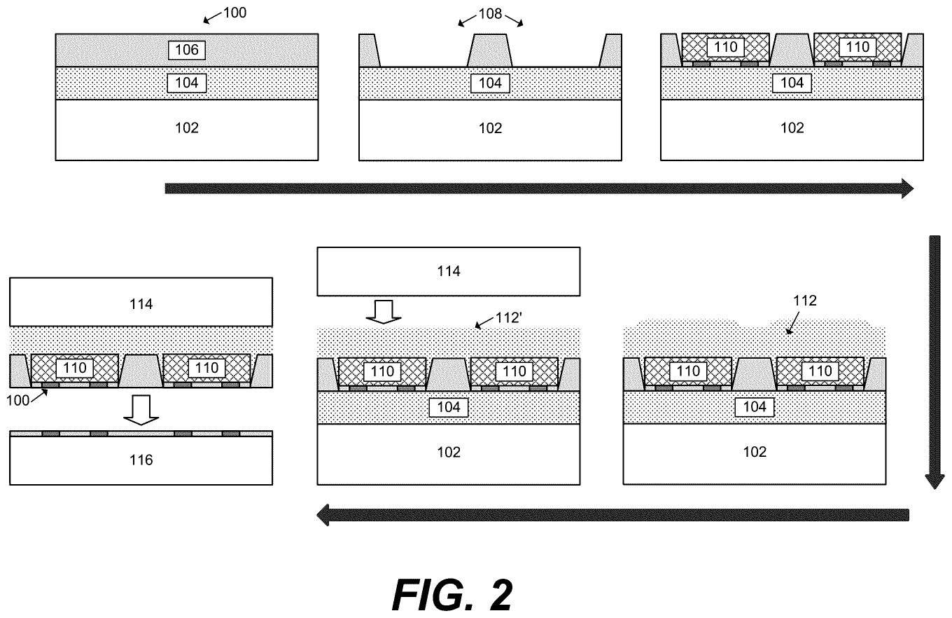

FIG. 2 illustrates one implementation of a process for creating a reconstituted wafer or panel for hybrid bonding applications. A substrate 100 is provided that may be a silicon on insulator (SOI) substrate formed according to conventional techniques. Such an SOI substrate may have a first semiconductor region 102, a dielectric layer 104 (e.g., a buried oxide) over the first semiconductor region 102, and a second semiconductor region 106 over the buried oxide 104. The second semiconductor region 106 may be modified to have a plurality of recesses 108 exposing the underlying buried oxide 104, each recess having a shape and size configured to accommodate a die 110. For example, the recess may be up to 5-10 um deep to have a thickness that is similar to the thickness of the dies 110. This will allow less undulation of the planarizing layer between adjacent dies 110 as the second semiconductor region 106 will make up some of the height differentiation between the dies and buried oxide layer 104.

Alternatively, a substrate 100 of any suitable material may be used with an overlying dielectric 104 and an overlying layer 106 can be any suitable material that can be selectively patterned relative to the dielectric 104.

Using the SOI example, a plurality of semiconductor dies 110 are then bonded to the buried oxide 104 through the plurality of recesses. This bond may be formed using direct bonding techniques, though other techniques such as adhesive bonding or hybrid bonding techniques may, in certain instances, be utilized. The dies 110 may be less than 10 um, or in some cases, less than 5 um in thickness.

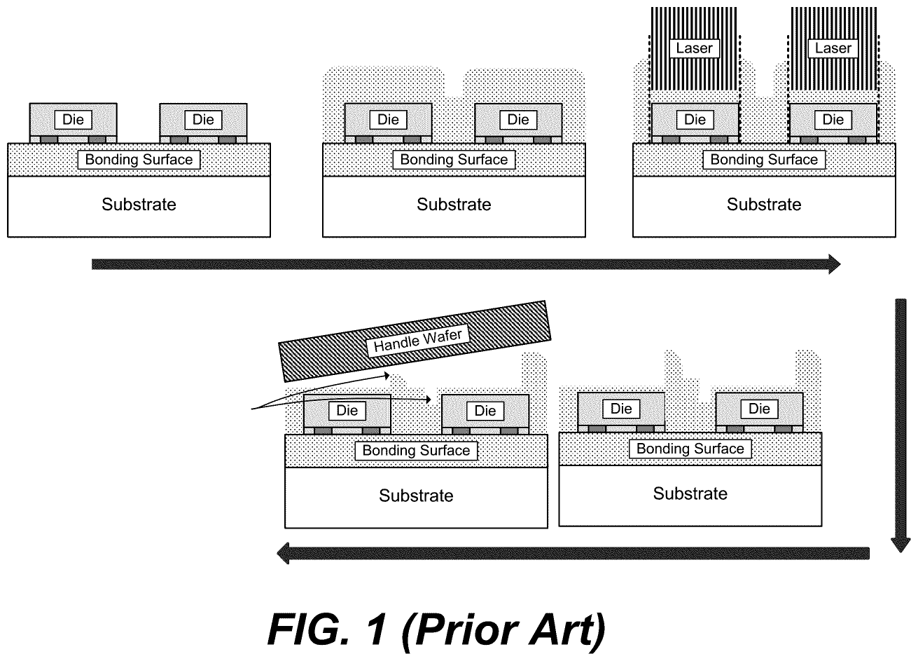

A planarizing layer 112 may be formed over the second semiconductor region and the semiconductor dies 110. The planarizing layer 112 may be an oxide, nitride, carbide, etc. and may be formed by thermal growth, chemical vapor deposition (CVD), physical vapor deposition (PVD), atomic layer deposition (ALD), tetraethyl orthosilicate (TEOS) process, etc. According to one example implementation, the planarizing layer 112 comprises silicon oxide formed by a conventional TEOS process to be less than 10 um thick, or in some cases substantially less than 3 um thick. The layer may be substantially thinner than in the conventional process shown in FIG. 1 as the surface will be more planar due to the presence of the second semiconductor region 106 between dies reducing the height differential. Thus, laser ablation, which could damage the underlying dies 110, will not be required.

A planarizing process, such as CMP, may then be performed to the planarizing layer 112 to reduce surface variation of the planarizing layer 112 and leave a more planarized planarizing layer 112′. Laser ablation may not be required to process the planarizing layer 112 as the variation in surface height of the planarizing layer 112 may be sufficiently small as to be effectively planarized with CVD alone.

A handle wafer 114 may then be bonded to the planarizing layer 112′ after performing the CMP process. The handle wafer 114 may be a semiconductor or dielectric wafer and may be direct bonded with the planarizing layer 112′. The handle wafer 114 provides rigid support of the dies 110, planarizing layer 112′, and second semiconductor region 106, which may be relatively thin, e.g., 10 um or less.

The first semiconductor region 102 may then be removed from the buried oxide 104 layer after bonding the handle wafer 114 to the planarizing layer 112′. This may be accomplished using conventional debonding techniques or by etching the region until it is completely removed. Additionally or alternatively, the buried oxide 104 may be removed from the second semiconductor region 106 and dies 110. In one embodiment, the buried oxide 104 is removed to cause the separation of the first semiconductor region 102 from other the substrate elements. In another embodiment, after separating the first semiconductor region 102 from the buried oxide layer 104, the buried oxide region 104 is removed (e.g. by etching) to expose the dies 110 and the second semiconductor region 106.

The dies 110 may be provided with hybrid bonding surfaces 118 on one or both major surfaces of each die 110, such hybrid bonding surfaces having a combination of dielectric regions and conductive regions for forming elements of an active circuit after bonding. Removing the buried oxide layer 104 exposes the hybrid bonding surfaces 118 of the dies 110 that were facing, and bonded to, the buried oxide region 104. Certain known bond surface preparation steps such as cleaning and/or activating, etc. may be performed on the exposed hybrid bonding surfaces 118, such steps well known in the field of hybrid bonding and thus omitted for the sake of simplicity. A hybrid bonding process may then be performed to physically bond and electrically connect the dies 110 to one or more functional substrates 116.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for manufacturing semiconductor packages, comprising:
providing a silicon on insulator (SOI) substrate having:
a first semiconductor region,
a buried oxide layer over the first semiconductor region, and
a second semiconductor region over the buried oxide layer, the second semiconductor region having a plurality of recesses exposing the underlying buried oxide layer, each recess having a shape and size configured to accommodate a semiconductor die; and
bonding a plurality of semiconductor dies to the buried oxide through the plurality of recesses.

2. The method of claim 1, further comprising forming a planarizing layer over the second semiconductor region and the semiconductor dies.

3. The method of claim 2, further comprising performing a chemical mechanical polish (CMP) process to the planarizing layer to reduce surface variation of the planarizing layer.

4. The method of claim 3, further comprising bonding a handle wafer to the planarizing layer after performing the CMP process.

5. The method of claim 4, further comprising separating the first semiconductor region from the buried oxide layer after bonding the handle wafer to the planarizing layer.

6. The method of claim 4, further comprising separating the first semiconductor region after bonding the handle wafer to the planarizing layer by removing the buried oxide from the second semiconductor region and the semiconductor dies.

7. The method of claim 5, wherein after separating the first semiconductor region from the buried oxide layer, the method further comprises removing the buried oxide region to expose the semiconductor dies and the second semiconductor region.

8. The method of claim 7, wherein exposing the semiconductor dies exposes hybrid bonding surfaces of the dies.

9. The method of claim 8, further comprising performing a hybrid bonding process to physically bond and electrically connect the semiconductor dies to one or more functional substrates.

10. A method for manufacturing semiconductor packages, comprising:
providing a substrate with a dielectric layer and a patterned layer having a plurality of recesses exposing portions of the dielectric layer, each recess having a shape and size configured to accommodate a semiconductor die; and
bonding a plurality of semiconductor dies to the dielectric layer through the plurality of recesses.

11. The method of claim 10, further comprising forming a planarizing layer over the patterned layer and the semiconductor dies.

12. The method of claim 11, further comprising performing a planarizing process to the planarizing layer to reduce surface variation of the planarizing layer.

13. The method of claim 12, wherein the planarizing process is implemented using a CMP process.

14. The method of claim 12, further comprising bonding a handle wafer to at least one of the planarizing layer or the semiconductor dies after performing the planarizing process.

15. The method of claim 14, further comprising separating the substrate from the dielectric layer after bonding the handle wafer to the at least one of the planarizing layer or the semiconductor dies.

16. The method of claim 14, wherein after bonding the handle wafer to the at least one of the planarizing layer or the semiconductor dies, the method further comprises separating the substrate by removing the dielectric layer from the patterned layer and the semiconductor dies.

17. The method of claim 15, wherein after separating the substrate from the dielectric layer, the method further comprises removing the dielectric layer to expose the semiconductor dies and the patterned layer.

18. The method of claim 17, wherein exposing the semiconductor dies exposes hybrid bonding surfaces of the dies.

19. The method of claim 18, further comprising performing a hybrid bonding process to physically bond and electrically connect the semiconductor dies to one or more functional substrates.
